(19) United States
(12) Patent Application Publication
(10) Pub. No.: US 2011/0281439 A1
(43) Pub. Date: Nov. 17, 2011

(54) APPLYING WAFER BACKSIDE COATINGS TO SEMICONDUCTOR WAFERS

(76) Inventors: Stephen Aldo Ruatta, South Pasadena, CA (US); Paul James Gleeson, Torrance, CA (US); Anthony Winster, Cambridge (GB); Fidelin N. Willybiro, West New York, NJ (US)

(21) Appl. No.: 13/102,094

(22) Filed: May 6, 2011

Related U.S. Application Data
(60) Provisional application No. 61/334,368, filed on May 13, 2010.

(51) Int. Cl. H01L 21/30

(52) U.S. Cl. 438/758; 257/E21.211

(57) ABSTRACT

A method for coating a silicon wafer comprises depositing a coating onto the exposed side of the wafer such that the coating is deposited on the entire surface area of the exposed side of the wafer, reaching to the edge of the wafer. This method either reduces significantly or eliminates die-fly during dicing of semiconductor wafers, and is effective for depositing thin layers, such as are needed for Al paste electrodes in solar cell fabrication.

### CROSS-REFERENCE TO RELATED APPLICATION

This application claims the benefit of U.S. Provisional Patent Application No. 61/334,368 filed May 13, 2010, the contents of which are incorporated herein by reference.

### FIELD OF THE INVENTION

This invention relates to a method for depositing coatings on electronic substrates, such as semiconductor wafers.

### BACKGROUND OF THE INVENTION

Adhesives are used frequently in the fabrication of electronic devices to attach the devices or components of the devices to substrates. In a particular application, dispensed paste adhesives are used to attach semiconductor dies to substrates. A drop of paste is dispensed through a dispensing head or needle onto the substrate; a die is picked up and contacted (with or without pressure) to the dispensed adhesive; and the assembly of die, paste adhesive, and substrate is baked at an elevated temperature to cure the adhesive.

One of the problems with using paste adhesive in semiconductor fabrication is that the adhesive flows and forms a fillet around the die, effectively increasing the footprint area of the die. When the die is very thin, the adhesive can flow up and over the side and onto the active face of the die, contaminating the circuitry or interfering with subsequent fabrication steps. In addition, paste adhesives are prone to resin bleed, requiring that space be left between the attached die and the surrounding bond pads so that the bond pads are not affected by excessive bleed. The need to include this additional surface area is counter to industry trends toward smaller devices.

Moreover, placing a die onto a dot of adhesive paste is a delicate operation. The force and time must be controlled to ensure that the adhesive has completely covered the underside of the die and has formed a uniform bond line. Paste adhesives sometimes do not dispense uniformly, causing tilting of the die and leading to immediate or long-term electrical failure of the semiconductor device. This is especially a problem as die become smaller because the dispensing operation and the placement operation are both more difficult to control with smaller die.

To overcome these limitations the industry has turned to the use of adhesive coatings applied to the entire backside of the silicon wafer, commonly known as wafer backside coatings (WBC). These coatings are typically applied by screen or stencil printing. After printing, the coated wafer is heated to evaporate solvent and/or partially advance the adhesive resin (known as B-staging), so that the coating is hardened to a non-tacky state. The wafer is then laminated onto a dicing tape with the backside adhesive coating in contact with the dicing tape. The wafer is then singulated into individual dies.

A common method to singulate the wafer into individual dies is a process generally referred to as sawing. Streets or pre-dicing lines are processed onto the wafer and subsequently mechanically abraded or eroded by a saw blade. The dies are held in their place on the wafer by the adhering the wafer onto the dicing tape. One of the problems with the application of the wafer backside coating using screen or stencil printing is that the coating is not applied fully to the edges of the wafer. Consequently, individual dies at the edge of the wafer fly off the dicing tape in a phenomenon called die fly or die fly-away. A fly-away die is subject to damage and unsuitable for use and can damage the dicing equipment, particularly the blade. In addition, the die may also be projected onto the top of the wafer surface, damaging other die on the wafer. Smaller and thinner dies are especially prone to die fly, and as the industry drives ever and ever to thinner and smaller dies, the problem becomes more costly.

The surfaces of silicon wafers for making solar cells are also coated during their fabrication process. The back surface is coated with a paste electrode made of Al, and the front surface is coated with a diffusion layer and an anti-reflection layer. The desire for thinner solar cells thrives also within the solar cell industry, but applying coatings to thin solar cells, particular thick coatings, can warp the solar cell. It is known that a decrease of the thickness of the Al paste electrode lessens warp. Thus, it would be a benefit to be able to apply thin coatings to solar cells to eliminate waste due to warping.

Thus, there is a need in the fabrication processes for silicon wafers or crystalline silicon wafers for a method of applying performance coatings all the way to the edges.

### SUMMARY OF THE INVENTION

As used throughout this specification and claims, the term “silicon wafer” or “wafer” will refer to silicon, gallium arsenide, germanium, or similar compound semiconductor materials as wafers that contain semiconductor circuitry and/or to silicon wafers that are or will become solar cells.

This invention is a method for coating a wafer that takes the coating to the edges of the wafer comprising
(i) providing a wafer that has two sides, one side of which will be exposed to the method of coating;
(ii) securing the wafer to a flat surface in a position such that one side of the wafer faces the flat surface and the other side of the wafer is exposed;
(iii) providing a stencil or a screen with a printing opening for printing, with the area of the printing opening larger than the area of the exposed side of the wafer;
(iv) positioning the stencil or screen over the wafer such that the edge of the printing opening is displaced away from the entire perimeter of the wafer, and such that the top of the stencil or screen is at a height from the exposed side of the wafer equal to a desired coating thickness; and
(v) depositing a coating onto the exposed side of the wafer such that the coating is deposited on the entire surface area of the exposed side of the wafer, reaching to the edge of the wafer.

In a further embodiment, a film is interposed between the one side of the wafer facing the flat surface and the flat surface. The film can be a porous film or an adhesive film with adhesive on one side or both sides. In the embodiment in which the film is a porous film, the wafer and porous film will be secured to the flat surface by vacuum suction. In the embodiment in which the film is an adhesive film with one adhesive side, the front side of the wafer will be in contact with the adhesive layer, and the adhesive film will be secured manually or mechanically (such as by weights or adhesive tape), or by vacuum, to the flat surface. In the embodiment in which the film has adhesive on both sides, the front side of the wafer will be in contact with one side of the adhesive film, and the flat surface will be in contact with the other side of the adhesive film so that the adhesive film adheres the wafer to the flat surface.

### BRIEF DESCRIPTION OF THE DRAWINGS

FIG. 1 is a depiction of a prior art set-up for stencil printing wafers.

FIG. 2 is a depiction of the inventive set-up for stencil printing wafers.

FIG. 3 is a depiction of a prior art set-up for screen printing wafers.

FIG. 4 is a depiction of the inventive set-up for screen printing wafers.

FIG. 5 is a depiction of a prior art assembly of wafer on dicing tape.

FIG. 6 is a depiction of the inventive assembly of wafer on dicing tape.

### DETAILED DESCRIPTION OF THE INVENTION

The invention will now be described in detail with reference to the Figures. In these Figures an adhesive tape is used to adhere the wafer to the flat surface, which typically is a pallet or a work stage.

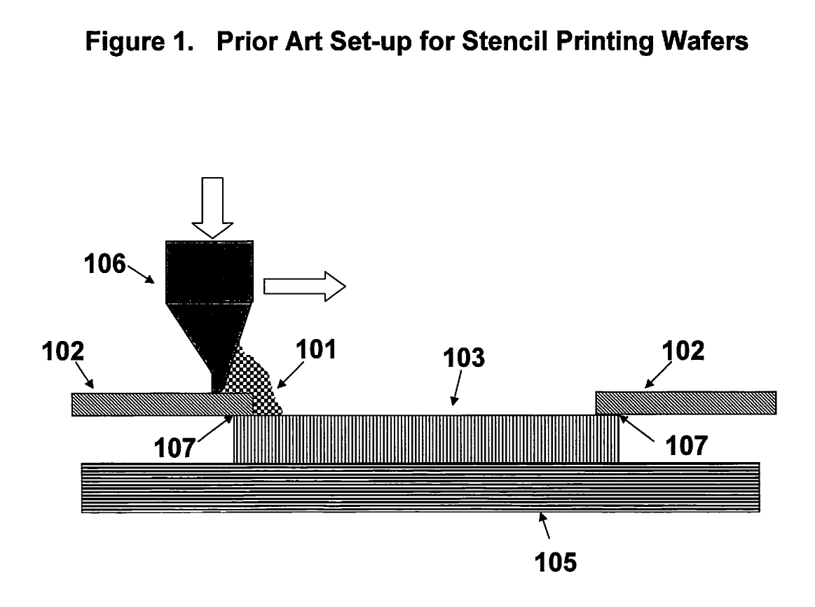

FIG. 1 shows a cross-sectional view of a prior art set-up and method for stencil printing wafers. A pallet 105 (flat surface) supports a wafer 103. A stencil 102 is placed on top of the wafer supported along the wafer's edges. An applicator 106 is positioned on the top of one side of the stencil and coating material 101 is placed in front of the applicator. By moving across the exposed side of the wafer, the applicator deposits the coating onto the wafer. The interface 107 of the stencil and wafer remains devoid of coating.

Subsequently, if the wafer is a semiconductor wafer, when the wafer is adhered by the coating to a dicing tape for singulation the interface 107 area is not securely attached to the dicing tape, and dies sawed from this area fly off the dicing tape. The dies are damaged or lost, and surrounding machinery or instrumentation can be damaged.

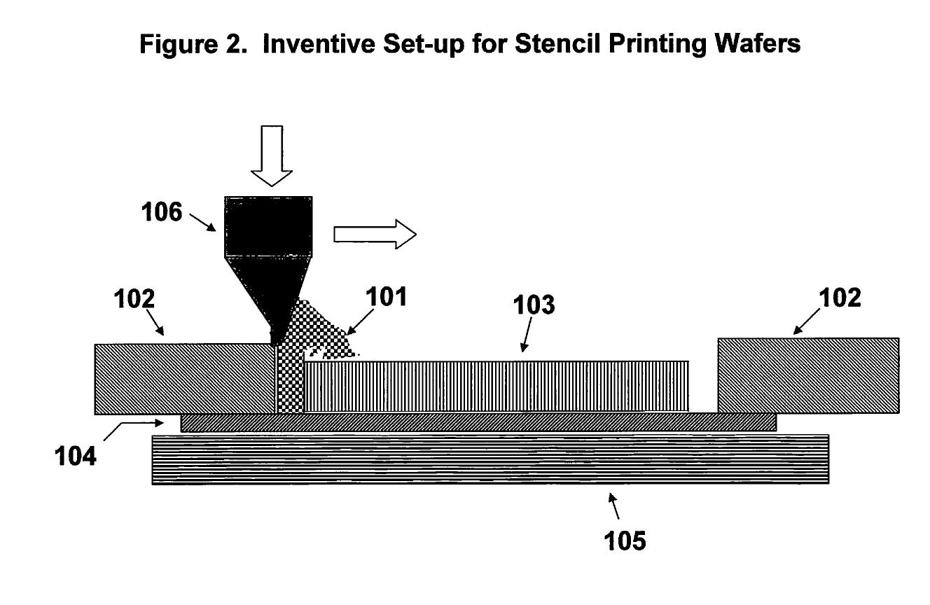

FIG. 2 shows a cross-sectional view of the inventive set-up and method for stencil printing wafers. A pallet 105 (flat surface) supports an adhesive film 104 and a wafer 103 on the adhesive film. The one side of the wafer is in contact with the adhesive film. The adhesive film has length and width dimensions sufficient to adhere the wafer to the pallet. A stencil 102 (with a printing opening having an area larger than the area of the exposed side of the wafer) is placed over the adhesive film 104 and wafer 103 with the stencil opening centered above the wafer, and positioned so that the entire perimeter of the wafer is exposed and does not support the stencil. In this FIG. 2, the stencil 102 is positioned on the adhesive film 104; however, the stencil could also be positioned on the pallet 105 (not shown in this figure). The applicator 106 is positioned on the top of the stencil and by moving across the exposed side of the wafer deposits the coating 101 onto the entire exposed side of the wafer all the way to its edges. In some embodiments, the applicator may start depositing coating before reaching the beginning edges of the wafer, and continue depositing off the ending edges of the wafer.

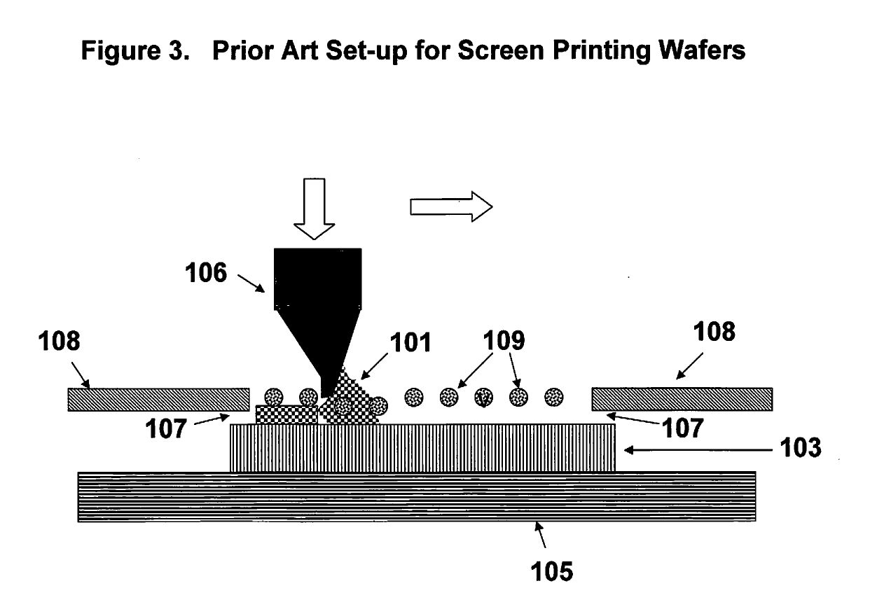

FIG. 3 shows a cross-sectional view of a prior art set-up for screen printing coatings onto the backside of wafers. A pallet 105 supports a wafer 103. A screen 108 with wires 109 is placed over the wafer along its edges. An applicator 106 is positioned on the top of one side of the screen and by moving across the exposed side of the wafer deposits a coating 101 onto the wafer. The interface 107 of the screen and wafer remains devoid of adhesive coating 101.

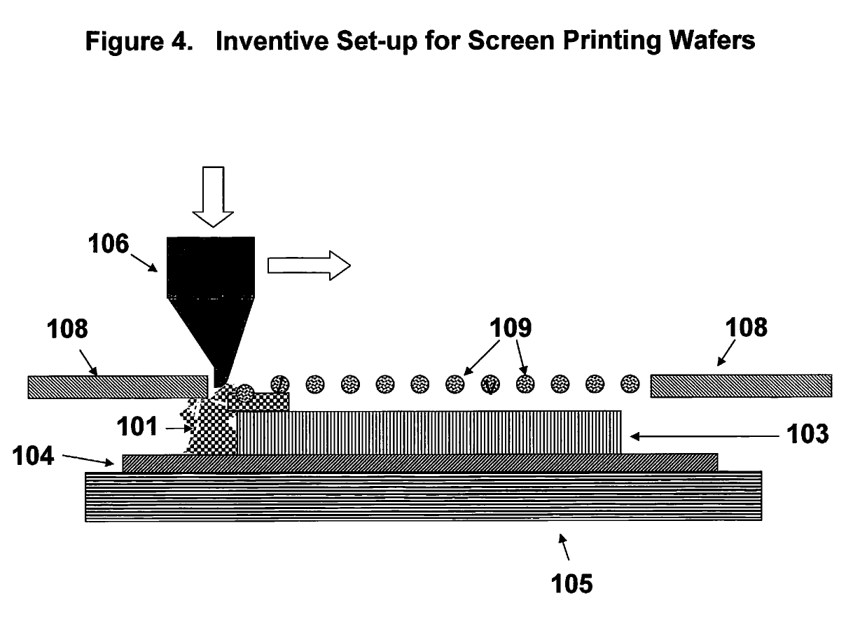

FIG. 4 shows a cross-sectional view of the inventive set-up and method for screen printing wafers. A pallet 105 (flat surface) supports an adhesive film 104 and a wafer 103 on the adhesive film. The front side of the wafer is in contact with the adhesive film. The adhesive film has length and width dimensions sufficient to adhere the wafer to the pallet. A screen 108 (with a printing opening having an area larger than the area of the exposed side of the wafer) is placed over the adhesive film 104 and wafer 103 with the screen opening centered above the wafer, and positioned so that the entire perimeter of the wafer is exposed and does not support the screen. In this FIG. 4, the screen 108 is positioned on the adhesive film 104; however, the screen could also be positioned on the pallet 105 (not shown in this figure). The applicator 106 is positioned on the top of one side of the screen and by moving across the exposed side of the wafer deposits the coating 101 onto the entire exposed side of the wafer all the way to its edges. In some embodiments, the applicator may start depositing coating before reaching the beginning edges of the wafer, and continue depositing off the ending edges of the wafer.

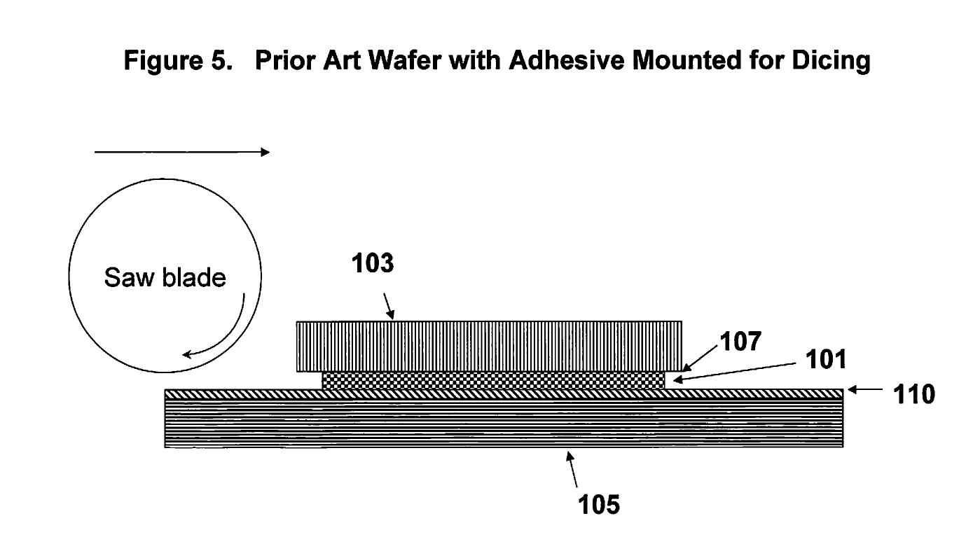

FIG. 5 is a cross-sectional view of a prior art assembly of semiconductor wafer 103, backside coating 101, and dicing tape 110, showing the area of the wafer 107 that is not coated with the backside coating.

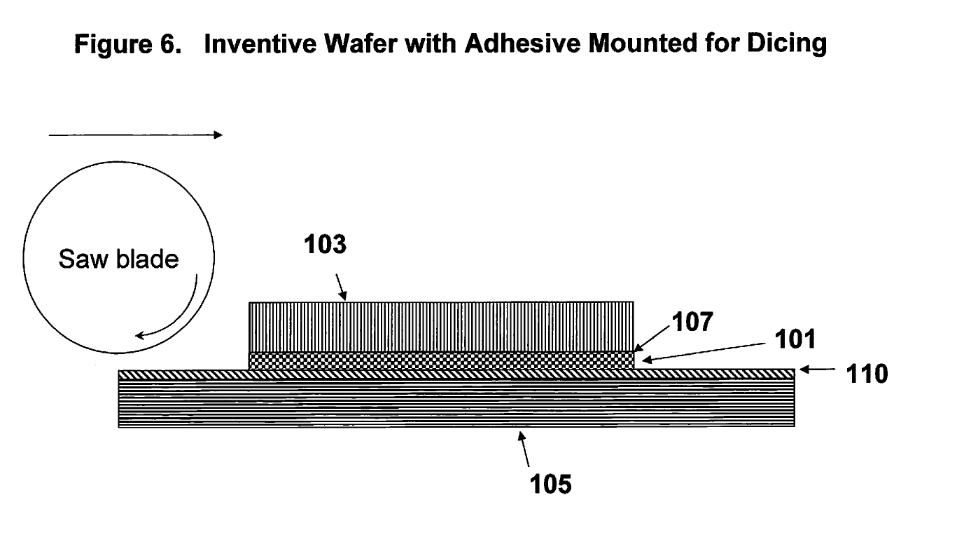

FIG. 6 is a cross-sectional view of the inventive assembly of a semiconductor wafer 103, backside coating 101, and dicing tape 110, showing that the entire backside surface of the wafer is coated completely to its edges.

The coating 101 can be any coating appropriate to the application. Suitable applications include backside coatings for wafers as herein described. Examples of resins for suitable semiconductor coatings include epoxies and oxetanes, maleimides with vinyl ethers, and acrylates. Examples of coatings for solar cells include aluminum paste, or diffusion and anti-reflectance coatings. The compositions of these coatings are known to those skilled in the art of solar cell fabrication. The coatings can be in form of a paste, or any paint or ink with sufficient viscosity and rheology to allow neat and effective coating to the wafer or other desired substrate.

The stencil 102 and screen 108 can be any stencil or screen used in the industry and appropriate to the application. In the case where a stencil is used, it is practicably difficult to use a stencil that is thinner than 37 microns because the edge of any stencil thinner than 37 microns has a tendency to crack and break. Using the method of this invention, the print thickness is the difference between the top surface of the stencil and the top surface of the wafer. By careful matching of the wafer and stencil thicknesses, very thin coating layers are able to be printed and the contact interface 107 between the stencil and the wafer can be eliminated.

The wafer 103 can be a complete or partial semiconductor silicon wafer having at least one region of semiconductor material on its active face. Typically, the exposed (backside or side to be coated) side of the wafer contains no regions of semiconductor material or circuitry. The wafer can also be a solar cell silicon wafer.

In those embodiments in which a film is used, the adhesive film 104 is any adhesive film with sufficient adhesion to hold the wafer during the coating operation. Typically, the film is a very low adhesion pressure sensitive adhesive. If the film is adhesive or tacky on only one side, the adhesive side is contacted to the one side of the wafer that will face the flat surface (work stage or pallet) and acts to protect the circuitry on that face. When there is tackiness on only one side of the film, the film can be manually or mechanically, or by vacuum, secured to the work stage or pallet.

If the film has adhesive on both sides, one adhesive side is contacted to the one side of the wafer to face the flat surface, and the second adhesive side is contacted to the flat surface to adhere the wafer and film to the flat surface.

The film can be a one layer film, in which the adhesion properties are the same on both sides, or the film can be a two layer film, in which the adhesion properties on the two sides of the film differ, one side with appropriate adhesion for adhering to the pallet or work stage, and the other side with appropriate adhesion for adhering to the wafer.

In other embodiments, a carrier tape is part of the film. In one embodiment, the carrier can be coated on only one side with adhesive, and is used in the same way as the adhesive film tacky on only one side. In another embodiment, the carrier can be coated on both sides with adhesive, either the same adhesive, or two different adhesives, one side with appropriate adhesion for adhering to the work stage or pallet, and the other side with appropriate adhesion for adhering to the wafer

In one embodiment, the film is an air permeable tape devoid of adhesive (for example, “Ultrahigh-Molecular-Weight Polyethylene Porous Film SUNMAP” made by Nitto) of sufficient weight and thickness to be held to the coating pallet with a vacuum provided from under the pallet, the permeation allowing both tape and wafer to be held in place by vacuum.

In a further embodiment, the adhesive film can be a two layer film in which a tacky adhesive that can be hardened by UV light is deposited on a carrier tape. To release the coated wafer, UV light is applied to harden the adhesive and reduce its adhesive properties.

In those embodiments in which a film is used, the front active face of the semiconductor wafer is protected by the film from potential damage that may be caused by the work stage or pallet (flat surface). In addition to protecting the wafer, the film can also protect the flat surface from coating deposits. In those embodiments in which the film extends beyond the entire perimeter of the wafer and the printing process applies the coating not just to the edges of the wafer but over the edges and onto the film, the film shields the flat surface from the coating. After the coating, the wafer is removed from the film and the film can be discarded. Alternatively, the work surface may need to be cleaned from excess coating between coating runs.

In another embodiment, the film between the flat surface and wafer is eliminated. In this embodiment, vacuum suction can be used to hold the wafer to the flat surface.

The flat surface is typically a pallet or work stage of sufficient size appropriate to the intended use. Such pallets are in use within the industry and are commonly called wafer pallets. When vacuum suction is to be used to hold the wafer to the stage or pallet, the stage or pallet will have effectively placed and a sufficient number of holes through which vacuum suction can be applied to hold the wafer, and film if any.

The applicator 106 can be any applicator appropriate to the intended use. A tool, such as a squeegee, is currently widely used in the industry. The applicator can be used with or without pressure. If used with pressure, the pressure can be set to a desired level to shear thin the coating during application.

What is claimed:

1. A method for coating a wafer comprising:
(i) providing a wafer that has two sides, one side of which will be exposed to the method of coating;
(ii) securing the wafer to a flat surface in a position such that one side of the wafer faces the flat surface and the other side of the wafer is exposed;
(iii) providing a stencil or a screen with a printing opening for printing, with the area of the printing opening larger than the area of the exposed side of the wafer;
(iv) positioning the stencil or screen over the wafer such that the edge of the printing opening is displaced away from the entire perimeter of the wafer, and such that the top of the stencil or screen is at a height from the exposed side of the wafer equal to a desired coating thickness;
(v) depositing a coating onto the exposed side of the wafer such that the coating is deposited on the entire surface area of the exposed side of the wafer, reaching to the edge of the wafer.

2. The method of claim 1 in which a film is interposed between the one side of the wafer facing the flat surface and the flat surface.

3. The method of claim 2 in which the film is a porous film.

4. The method of claim 2 in which the film is an adhesive film with adhesive on one side or both sides of the film.
